(19) United States
(12) Patent Application Publication
(10) Pub. No.: US 2010/0132611 A1
(43) Pub. Date: Jun. 3, 2010

(54) Substrate Processing System

(75) Inventor: Yoshitaka Koyama, Toyama-shi (JP)

Correspondence Address: OLIFF & BERRIDGE, PLC, P.O. BOX 320850, ALEXANDRIA, VA, 22320-4850, US

(73) Assignee: HITACHI KOKUSAI ELECTRIC INC., TOKYO (JP)

(21) Appl. No.: 12/224,899

(22) PCT Filed: Mar. 20, 2007
(86) PCT No.: PCT/JP2007/055678

§ 371 Date: Jun. 8, 2009

(30) Foreign Application Priority Data
Mar. 23, 2006 (JP) 2006-081153

(51) Int. Cl. H01L 21/465

(52) U.S. Cl. 118/696; 257/E21.485

(57) ABSTRACT

A substrate processing system is provided, in which collection data transmitted from a substrate processing apparatus can be easily used. A substrate processing system includes a substrate processing apparatus, and a group control apparatus connected to the substrate processing apparatus, wherein the group control apparatus comprises accumulation means for accumulating collection data transmitted from the substrate processing apparatus, storage part for correlating hardware information of components configuring the substrate processing apparatus with previously set element name information and then storing such correlated information, and a memory for correlating the hardware information with the collection data transmitted from the substrate processing apparatus and then memorizing such correlated information.

### TECHNICAL FIELD

The present invention relates to a substrate processing system including a substrate processing apparatus, and a group control apparatus connected to the substrate processing apparatus.

### BACKGROUND ART

As this type of substrate processing system, a system is known, in which a substrate processing apparatus periodically collects an opening/closing signal of a gas valve, or detection data such as a detection value of furnace temperature through a subsystem such as a gas control unit or temperature control unit, and memorizes the data into memory part of the substrate processing apparatus. Moreover, a system is known, which has a function of transmitting collected detection data to a administrative apparatus outside the substrate processing apparatus via a network.

### DISCLOSURE OF THE INVENTION

However, there has been a problem that when the detection data or the like are collected by the administrative apparatus, if a data structure, or a decimal point position and measurement unit of each data is changed due to modification of a hardware configuration of a substrate processing apparatus, the administrative apparatus cannot recognize such change. Moreover, there has been a problem that when a data name or the like of the detection data are changed at a administrative apparatus side, the data cannot be mapped with detection data at a side of the substrate processing apparatus.

The invention is intended to solve the conventional problem, and an object of the invention is to provide a substrate processing system in which collection data transmitted from the substrate processing apparatus can be easily analyzed and used.

To solve the above problem, a first feature of the invention resides in a substrate processing system including a substrate processing apparatus for performing processing to a substrate, and at least one, group control apparatus connected to the substrate processing apparatus; wherein the group control apparatus comprises accumulation part for accumulating collection data transmitted from the substrate processing apparatus; storage part for connecting hardware information of components configuring the substrate processing apparatus with previously set element name information, and then storing such connected information; and memory part for connecting the hardware information with the collection data transmitted from the substrate processing apparatus, and then memorizing such connected information.

A second feature of the invention resides in at least one group control apparatus that is connected to a substrate processing apparatus for performing processing to a substrate, and comprises accumulation part for accumulating collection data transmitted from the substrate processing apparatus, storage part for correlating hardware information of components configuring the substrate processing apparatus with previously set element name information, and then storing such correlated information, and memory part for correlating the hardware information with the collection data transmitted from the substrate processing apparatus, and then memorizing such correlated information.

A data collection method of the invention includes, in a substrate processing system including a substrate processing apparatus for performing processing to a substrate, and at least one group control apparatus connected to the substrate processing apparatus, a step of accumulating collection data transmitted from the substrate processing apparatus by accumulation part of the group control apparatus, a step of, by storage part of the group control apparatus, correlating hardware information of components configuring the substrate processing apparatus with previously set element name information, and then storing such correlated information, and a step of, by memory part of the group control apparatus, correlating the hardware information with the collection data transmitted from the substrate processing apparatus, and then memorizing such correlated information.

### ADVANTAGES OF THE INVENTION

According to the invention, since memory part correlates data including at least hardware information of a substrate processing apparatus with collection data transmitted from the substrate processing apparatus, and then memorizes the correlated data, the collection data transmitted from the substrate processing apparatus can be easily analyzed and used.

### BRIEF DESCRIPTION OF THE DRAWINGS

FIG. 1 shows a perspective diagram showing a substrate processing apparatus according to a first embodiment of the invention;

FIG. 2 shows a perspective side diagram showing the substrate processing apparatus according to the first embodiment of the invention;

FIG. 3 shows a schematic diagram showing a configuration of a substrate processing system according to the first embodiment of the invention;

FIG. 4 shows a block diagram showing a detailed configuration of the substrate processing system according to the embodiment of the invention;

FIG. 5 shows a block diagram showing an input channel in the substrate processing apparatus of the substrate processing system according to the embodiment of the invention;

FIG. 6 shows data tables used in the substrate processing system according to the embodiment of the invention, wherein (a) shows a data definition table, (b) shows a data collection table, and (c) shows a data display table;

FIG. 7 shows data collection processing according to the embodiment of the invention, wherein (a) shows a flowchart for explaining data collection processing in the substrate processing apparatus, and (b) shows a flowchart for explaining data collection processing in the group control apparatus;

FIG. 8 shows a schematic diagram showing a gas line used in a second embodiment of the invention;

FIG. 9 shows a table showing names and hardware position information used for sensors in the second embodiment of the invention;

FIG. 10 shows a table showing data names for each of sensors used in the second embodiment of the invention; and

FIG. 11 shows a diagram showing the data definition table used in the second embodiment of the invention.

### DESCRIPTION OF THE REFERENCE NUMERALS AND SIGNS

100 substrate processing apparatus
300 substrate processing system
302 group control apparatus
306 memory

### BEST MODE FOR CARRYING OUT THE INVENTION

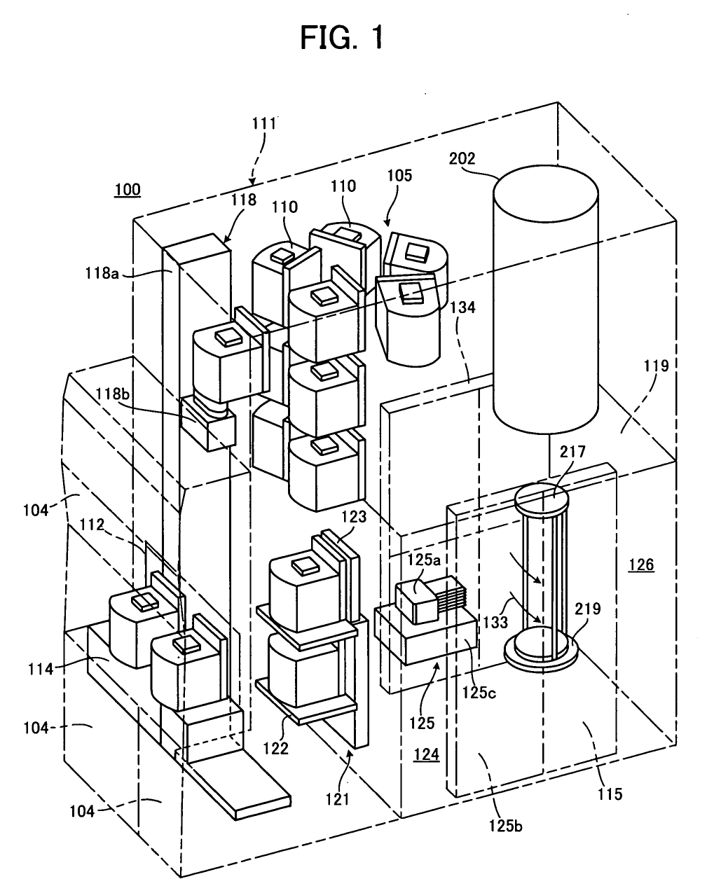

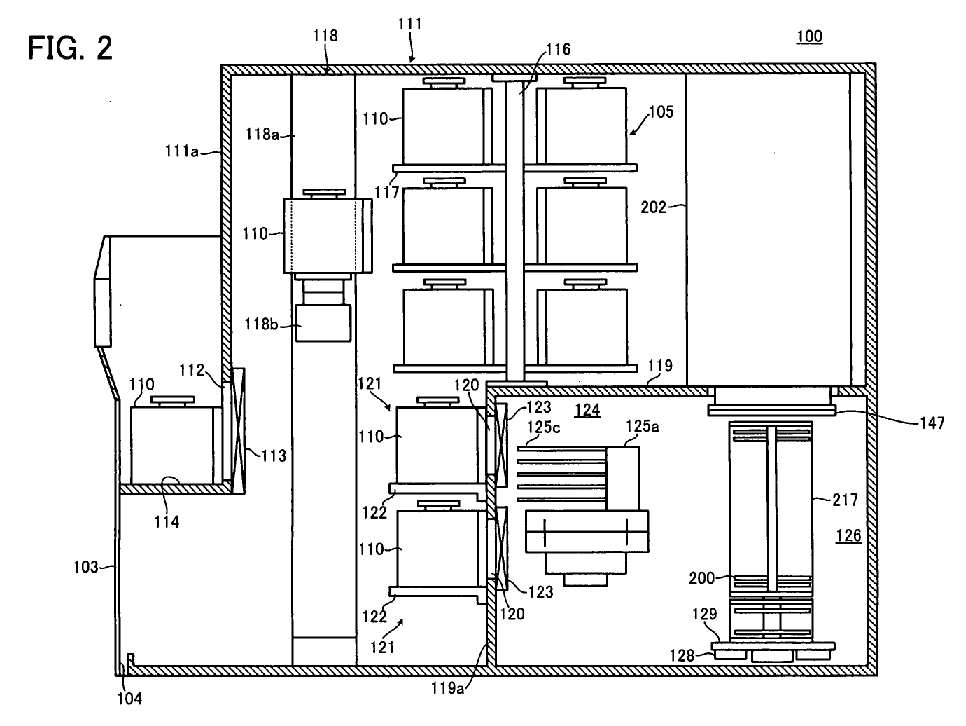

In a first best mode for carrying out the invention, for example, a substrate processing apparatus is configured as a semiconductor manufacturing apparatus for embodying a processing apparatus in a manufacturing process of a semiconductor device (IC). The following description is made on a case that a vertical apparatus is used as a substrate processing apparatus, which performs oxidation, diffusion processing, CVD processing and the like to a substrate (hereinafter, simply called processing apparatus). FIG. 1 shows a perspective diagram of the substrate processing apparatus used in the invention. FIG. 2 is a perspective side diagram of the substrate processing apparatus shown in FIG. 1.

As shown in FIGS. 1 and 2, a substrate processing apparatus 100 of the invention has a housing 111, in which a FOUP (Front Opening Unified Pod, hereinafter called pod) 110 is used as a wafer carrier accommodating a wafer (substrate) 200 including silicon or the like. A front maintenance hatch 103 as an opening provided in a maintainable manner is opened in forward front of a front wall 111a of the housing 111, and front maintenance doors 104, 104 are built in the housing for opening and closing the front maintenance hatch 103 respectively.

A pod loading/unloading hatch (substrate container loading/unloading hatch) 112 is opened in the front wall 111a of the housing 111 so as to communicate between the inside and the outside of the housing 111, and the pod loading/unloading hatch 112 is opened and closed by a front shutter (substrate-container loading/unloading hatch opening/closing mechanism) 113.

A load port (substrate container passing stage) 114 is installed at a forward front side of the pod loading/unloading hatch 112, and the load port 114 is configured such that the pod 110 is set and positioned thereon. The pod 110 is loaded onto the load port 114 by an in-process carrier unit (not shown), and unloaded from a position on the load port 114 thereby.

A rotary pod rack (substrate container setting rack) 105 is installed in an upper side in an approximately center in a back and forth direction within the housing 111, and the rotary pod rack 105 is configured to keep a plurality of pods 110. That is, the rotary pod rack 105 has a post 116 that is vertically stood and intermittently rotated in a horizontal plane, and a plurality of rack boards (substrate container setting stages) 117 that is radially supported by the post 116 at respective positions of top, middle, and bottom stages, and each of the plurality of rack boards 117 is configured to keep a plurality of pods 110 with being set on the rack board respectively.

A pod carrier unit (substrate container carrier unit) 118 is installed between the load port 114 and the rotary pod rack 105 in the housing 111. The pod carrier unit 118 includes a pod elevator (substrate container raising/lowering mechanism) 118a that can be raised and lowered while holding the pod 110, and a pod carrier mechanism (substrate container carrier mechanism) 118b as a carrier mechanism. The pod carrier unit 118 is configured to carry the pod 110 between the load port 114, the rotary pod rack 105, and a pod opener (substrate container lid opening/closing mechanism) 121 by continuous operation of the pod elevator 118a and the pod carrier mechanism 118b.

A sub housing 119 is formed over a rear end in a lower side in the approximately center in the back and forth direction within the housing 111. A pair of wafer loading/unloading hatches (substrate loading/unloading hatches) 120 for loading and unloading the wafer 200 are opened in a front wall 119a of the sub housing 119 with being vertically arranged in upper and lower two stages, and a pair of pod openers 121, 121 are installed in the wafer loading/unloading hatches 120, 120 in the upper and lower stages. The pod openers 121 have setting stages 122, 122 for setting the pods 110, and cap attaching/detaching mechanisms (lid attaching/detaching mechanisms) 123, 123 for attaching and detaching the caps (lids) of the pods 110. The pod opener 121 is configured such that it attaches and detaches the cap of the pod 110 set on the setting stage 122 by the cap attaching/detaching mechanism 123 to open and close a wafer inlet/outlet of the pod 110.

The sub housing 119 configures a transfer room 124 that is fluidicly isolated from a space for installing the pod carrier unit 118 and the rotary pod rack 105. A wafer transfer mechanism (substrate transfer mechanism) 125 is installed in a front area of the transfer room 124. The wafer transfer mechanism 125 includes a wafer transfer unit (substrate transfer unit) 125a that can rotate or translate the wafer 200 in a horizontal direction, and a wafer transfer unit elevator (substrate transfer unit raising/lowering mechanism) 125b for raising and lowering the wafer transfer unit 125a. As schematically shown in FIG. 1, the wafer transfer unit elevator 125b is installed between a right end of the pressure-tight housing 111 and a right end of a front area of the transfer room 124 in the sub housing 119. The wafer transfer mechanism 125 is configured such that the wafer transfer unit elevator 125b and the wafer transfer unit 125a are continuously operated, so that the wafers 200 are charged and discharged into/from a boat (substrate holding tool) 217 using tweezers (substrate holders) 125c of the wafer transfer unit 125a as a setting section of the wafers 200.

In a backside area of the transfer room 124, a waiting region 126 that accommodates the boat 217 for waiting is formed. A treatment furnace 202 is installed in the upper side of the waiting region 126. A lower end of the treatment furnace 202 is configured to be opened and closed by a throat shutter (throat opening/closing mechanism) 147.

As schematically shown in FIG. 1, a boat elevator (substrate holding tool raising/lowering mechanism) 115 for raising and lowering the boat 217 is installed between the right end of the pressure-tight housing 111 and a right end of the waiting region 126 in the sub housing 119. A seal cap 219 as a lid is horizontally fixed to an arm 128 as a connection member connected to the raising/lowering stage of the boat elevator 115, and the seal cap 219 is configured such that it vertically supports the boat 217, and can close the lower end of the treatment furnace 202.

The boat 217 has a plurality of holding members, and is configured such that it horizontally holds a plurality of (for example, about 50 to 125) wafers 200 while the wafers are vertically arrayed with their centers being aligned.

As schematically shown in FIG. 1, a cleaning unit 134 including a supply fan and a dust-proof filter is installed in a left end of the transfer room 124, which corresponds to a side opposite to a side of each of the wafer transfer unit elevator 125b and the boat elevator 115, so that clean air 133 being a cleaned atmospheric gas or an inert gas is supplied. Moreover, while not shown, a notch alignment unit 135 as a substrate aligning unit for aligning wafers in position in a circumferential direction is installed between the wafer transfer unit 125a and the cleaning unit 134.

The clean air 133 blown from the cleaning unit 134 is flown into the boat 217 in the waiting region 126 through the notch alignment unit 135 and the wafer transfer unit 125a, then sucked by a not-shown duct to be exhausted to the outside of the housing 111, or to be circulated up to a primary side (supply side) as a sucking side of the cleaning unit 134 so as to be blown into the transfer room 124 by the cleaning unit 134 again.

Next, operation of the substrate processing apparatus 100 of the invention is described.

As shown in FIGS. 1 and 2, when the pod 110 is supplied onto the load port 114, the pod loading/unloading hatch 112 is opened by the front shutter 113, and the pod 110 on the load port 114 is loaded by the pod carrier unit 118 into the housing 111 through the pod loading/unloading hatch 112.

The loaded pod 110 is automatically carried by the pod carrier unit 118 to a specified rack board 117 of the rotary pod rack 105 and passed thereto, and temporarily kept, then carried from the rack board 117 to one pod opener 121 and passed thereto, and temporarily kept, then carried from the rack board 117 to one pod opener 121 and transferred to the setting stage 122, or directly carried to the pod opener 121 and transferred to the setting stage 122. During this, the wafer loading/unloading hatch 120 of the pod opener 121 is closed by the cap attaching/detaching mechanism 123, and the clean air 133 is flown into the transfer room 124 and fills the room. For example, the transfer room 124 is filled with nitrogen gas as the clean air 133, and consequently oxygen concentration is set to be extremely low, 20 ppm or less, compared with oxygen concentration of the inside (air atmosphere) of the housing 111.

The pod 110 set on the setting stage 122 is pressed at its end face at an opening side to the periphery of an opening of the wafer loading/unloading hatch 120 in the front wall 119a of the sub housing 119, and a cap thereof is detached by the cap attaching/detaching mechanism 123 to open the wafer inlet/outlet.

When the pod 110 is opened by the pod opener 121, a wafer 200 is picked up from the pod 110 through the wafer inlet/outlet by the tweezers 125c of the wafer transfer unit 125a, then the wafer is subjected to alignment by the not-shown notch alignment unit 135, and then loaded into the waiting region 126 behind the transfer room 124, and charged into the boat 217 therein. The wafer transfer unit 125a that has passed the wafer 200 to the boat 217 is returned to the pod 110 to charge next wafer 110 into the boat 217.

During the charge operation of the wafer into the boat 217 by the wafer transfer mechanism 125 in one (upper or lower) pod opener 121, another pod 110 is carried by the pod carrier unit 118 from the rotary pod rack 105 to the other (lower or upper) pod opener 121 and transferred into that pod opener, and opening operation of the relevant pod 110 is concurrently performed by the relevant pod opener 121.

When the previously specified number of wafers 200 are charged into the boat 217, the lower end of the treatment furnace 202, which has been closed by the furnace shutter 147, is opened by the furnace shutter 147. Next, as the seal cap 219 is raised by the boat elevator 115, the boat 217 holding a group of the wafers 200 is accordingly loaded into the treatment furnace 202.

After the boat 217 is loaded, the wafers are subjected to optional treatment by the treatment furnace 202.

After the treatment, the wafers 200 and the pod 110 are discharged to the outside of the housing in a procedure opposite to the above except for the wafer aligning step by the not-shown notch alignment unit 135.

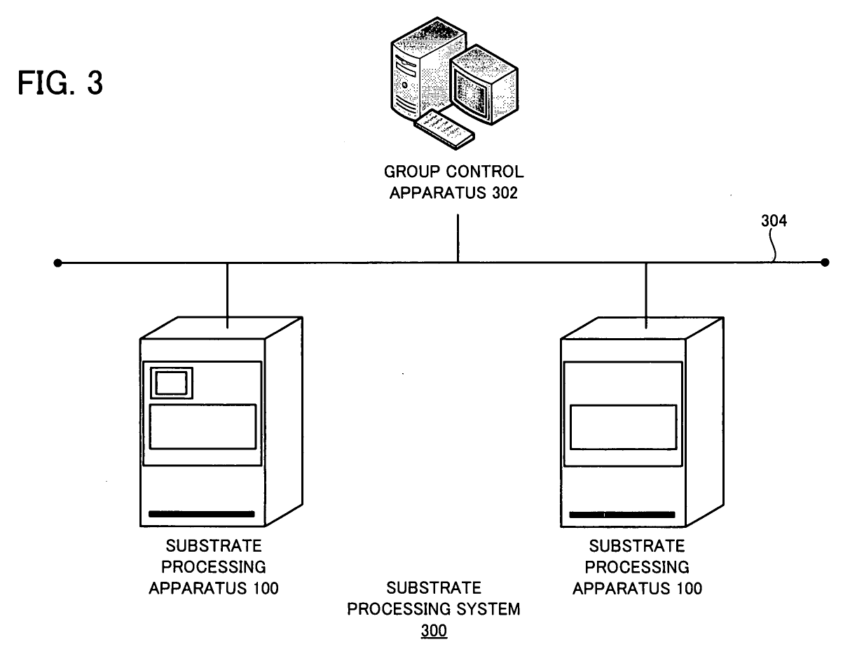

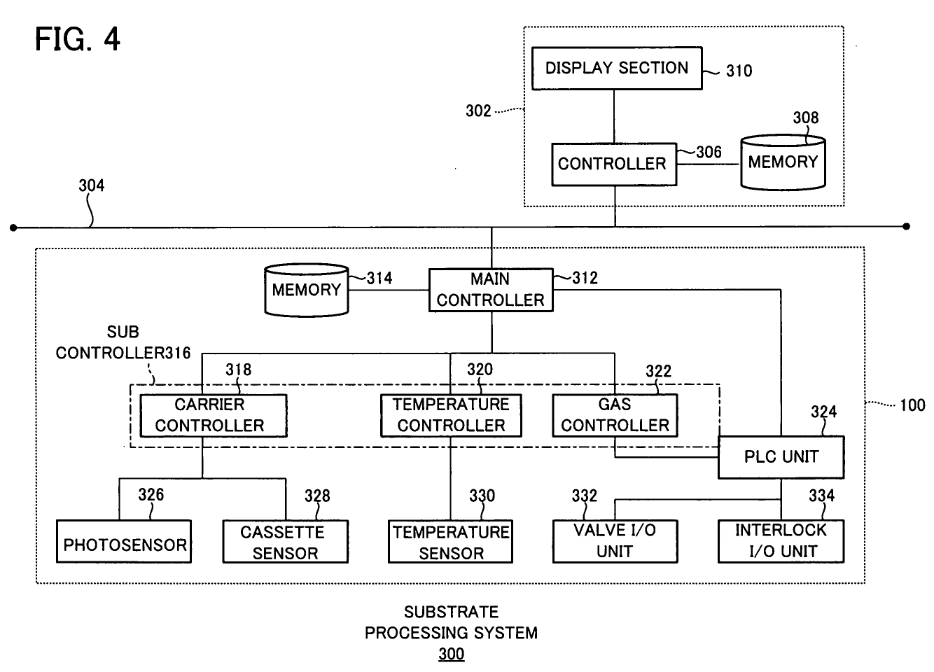

Next, an example of a substrate processing system 300 using the substrate processing apparatus 100 of the embodiment is described according to FIGS. 3 and 4.

As shown in FIG. 3, the substrate processing system 300 comprises a group control apparatus 302, at least one (two in the figure) substrate processing apparatus 100 as above, and a communication line 304 such as LAN (Local Area Network) communicating between the group control apparatus 302 and at least one (two in the figure) substrate processing apparatus 100.

FIG. 4 shows a configuration of hardware in the embodiment.

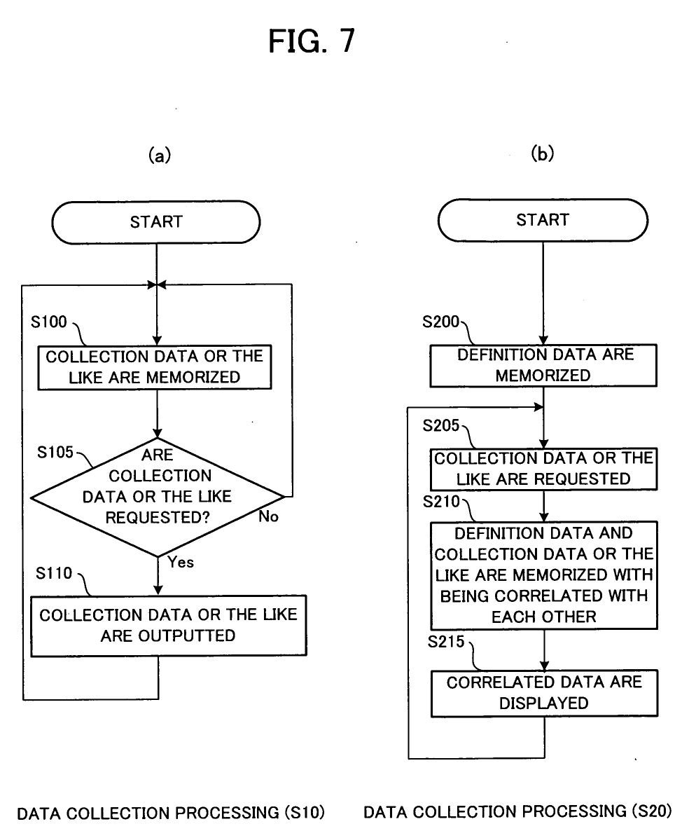

As shown in FIG. 4, the group control apparatus 302 comprises a controller 306, memory 308, and display section 310. The controller 306 performs input and output operation of data between the memory 308 and the display section 310. Moreover, the controller 306 has a first data collection program (as described later using FIG. 7), and performs input and output operation of data with respect to the substrate processing apparatus 100 via the communication line 304 according to the data collection program. The memory 308 memories (stores) data outputted from the controller 306, and outputs data memorized in the memory 308 to the controller 306. The display section 310 has a display screen 344 described later, and displays the data outputted from the controller 306 on the display screen 344. A type of data collected in the substrate processing apparatus 100, a data collection cycle, and an alarm generation condition and the like are set through operation of the display section 310.

The display section 310 may be an input and display section having display means and input means.

The substrate processing apparatus 100 has a main control system 312 and a sub control system 316. The main controller (main control system) 312 is connected with a memory 314 as memory means, and a sub controller (sub control system) 316 and the like. The sub controller 316 has a carrier control section (carrier controller) 318, temperature controller (temperature control section) 320, and gas controller (gas control section) 322. The carrier controller 318 is connected with a photosensor 326 and a cassette sensor 328. The temperature controller 320 is connected with a temperature sensor 330. The gas controller 322 is connected with a valve I/O unit 332 and an interlock I/O unit 334 via a PLC (Programmable Logic Controller) unit 324. The PLC unit 324 may be connected to the main controller 312 without passing through the gas controller 322.

The sub controller 316 actuates each actuator (not shown) based on setting data on respective controllers (carrier controller 318, temperature controller 320, and gas controller 322) outputted from the main controller 312, and newly controls operation of each actuator based on detection data outputted from the respective sensors (photosensor 326, cassette sensor 328, and temperature sensor 330).

The carrier controller 318 actuates an actuator (not shown) based on detection data (position detection data) outputted from the photosensor 326 to control operation of a carrier robot. Moreover, the carrier controller 318 actuates an actuator (not shown) based on detection data (detection data of a setting condition of a pod (cassette)) outputted from the cassette sensor 328 to control operation of a pod. The temperature controller 320 controls a heater (not shown) based on detection data (temperature detection data) outputted from the temperature sensor 330, and outputs the detection data to the main controller 312 in response to a request from the main controller 312. The gas controller 322 controls, via the PLC unit 324, a flow rate of gas supplied into a furnace. More specifically, the gas controller 322 controls a flow-rate control valve (not shown) based on detection data (gas flow-rate detection data) outputted from a mass flow controller described later, and outputs the detection data to the main controller 312 in response to a request from the main controller 312. The PLC unit 324 performs opening and closing control of a valve according to a sequence program or the like using valve opening/closing detection data outputted from the valve I/O unit 332, or an interlock signal outputted from the interlock I/O unit 334. Here, interlock refers to a protection circuit against wrong operation or malfunction of an apparatus.

Respective detection data outputted from respective sensors (photosensor 326, cassette sensor 328, and temperature sensor 330), and from respective input/output units (valve I/O unit 332 and interlock I/O unit 334) may include an analog signal or a digital signal (for example, a signal using a communication link such as RS-232C or DeviceNet). Moreover, input/output (I/O) of each of the sensors (photosensor 326, cassette sensor 328, and temperature sensor 330) may be controlled via a not-shown I/O control unit. The I/O control unit may be directly connected to the main controller 312, or may be connected to the main controller 312 via the sub controller 316.

The memory 314 collects (memories) data outputted from the main controller 312, and outputs data memorized in the memory 314 to the main controller 312. Moreover, the memory 314 stores data such as a recipe set by a user or control parameters for controlling respective units.

The main controller 312 monitors detection data of the respective sensors (photosensor 326, cassette sensor 328, and temperature sensor 330) outputted from the sub controller 316, and outputs setting data or the like on the respective controllers (carrier controller 318, temperature controller 320, and gas controller 322) to the sub controller 316 based on the detection data. Moreover, the main controller 312 has a second data collection program (described later using FIG. 7), and according to the second data collection program, the main controller collects (accumulates) the detection data of the respective sensors (photosensor 326, cassette sensor 328, and temperature sensor 330), which are outputted from the sub controller 316, into the memory 314 while associating the detection data with time data when the detection data are obtained (while marking time stamps to the detection data). Moreover, the main controller 312 may accumulate stores the collection data (detection data of the respective sensors (photosensor 326, cassette sensor 328, and temperature sensor 330) outputted from the sub controller 316) with time data (time stamps) (collects trace data) into nonvolatile memory means (not shown). Furthermore, the main controller 312 outputs the collection data or the like memorized in the memory 314 to the group control apparatus 302 in response to a request from the controller 306 of the group control apparatus 302. Consequently, the controller 306 of the group control apparatus 302 monitors and controls an operation condition of the main controller 312 of the substrate processing apparatus 100 using the collection data or the like.

For communication between the main controller 312 and the sub controller 316, a protocol specially designed for semiconductor manufacturing apparatuses such as SECS/HSMS, or protocols such as TCP/IP and XML/SOAP are used.

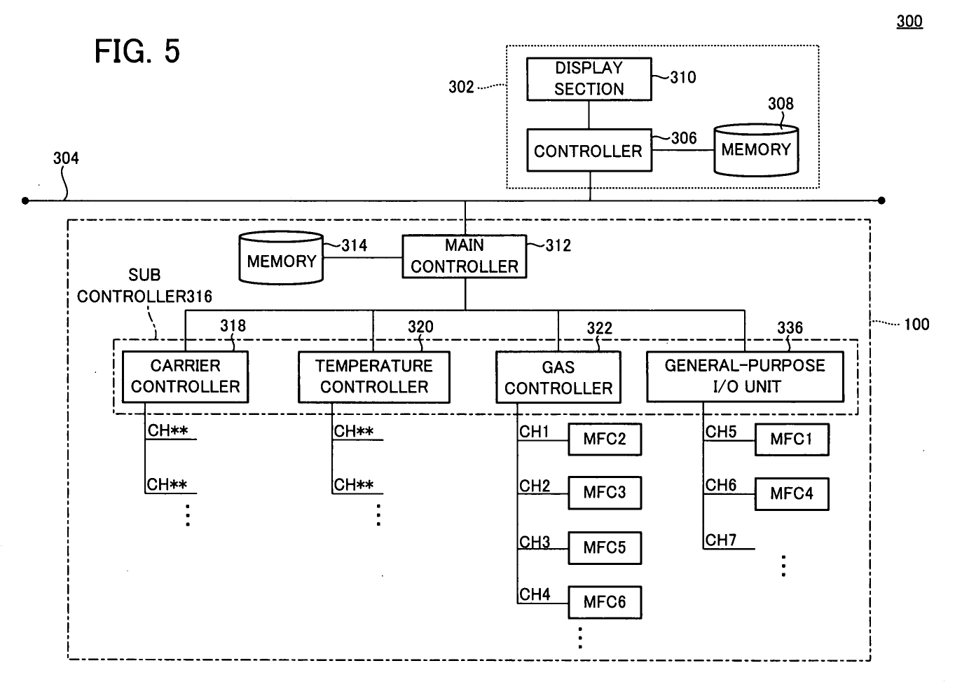

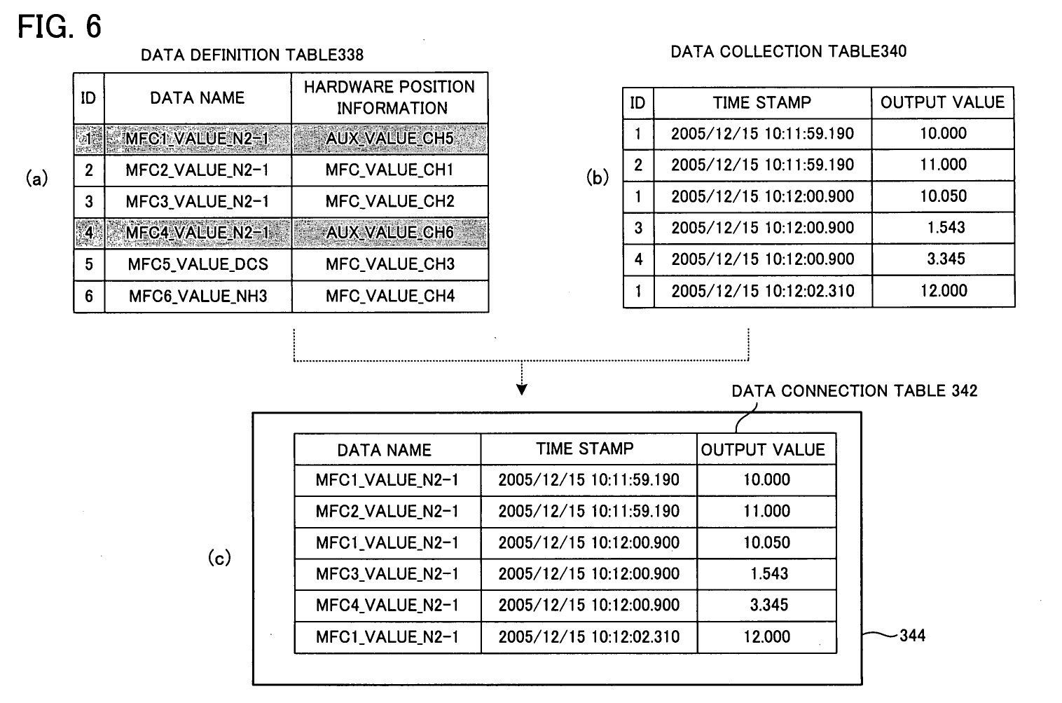

Next, an example of data collected by the substrate processing apparatus 100 and the control apparatus 302 of the substrate processing system 300 of the invention is described according to FIGS. 5 and 6.

As shown in FIG. 5, the substrate processing apparatus 100 has the main controller 312 described above. The main controller 312 has the carrier controller 318, the temperature controller 320, the gas controller 322, and a general-purpose I/O unit 336. The respective controllers (carrier controller 318, temperature controller 320, and gas controller 322), and the general-purpose I/O unit 336 have a plurality of input channels (for example, CH1 to CH7) respectively.

For example, the gas controller 322 has at least four input channels (CH1, CH2, CH3 and CH4), and each input channel is inputted with detection data (gas flow rate detection data) from each sensor (for example, mass flow controller (not shown)). More specifically, an input channel 1 (CH1) of the gas controller 322 is inputted with gas flow-rate detection data of a mass flow controller 2 (MFC2), an input channel 2 (CH2) is inputted with gas flow-rate detection data of a mass flow controller 3 (MFC3), an input channel 3 (CH3) is inputted with gas flow-rate detection data of a mass flow controller (MFC5), and an input channel 4 (CH4) is inputted with gas flow-rate detection data of a mass flow controller 6 (MFC6). The respective input channels (for example, CH1 to CH4) of the gas controller 322 are used exclusively as mass flow controller channels (MFC channels).

For example, the general-purpose I/O unit 336 has at least three input channels (CH5, CH6 and CH7), and each input channel is inputted with detection data (gas flow-rate detection data) from each sensor (for example, mass flow controller (not shown)). More specifically, an input channel 5 (CH5) of the general-purpose I/O unit 336 is inputted with gas flow-rate detection data of amass flow controller 1 (MFC1), and an input channel 6 (CH6) is inputted with gas flow-rate detection data of a mass flow controller 4 (MFC4). Each of the input channels of the general-purpose I/O unit 336 is used as a general-purpose channel to which detection data of various sensors in addition to the mass flow controller are inputted.

The MFC1 and MFC4 are fast-response mass flow controllers respectively, and the respective input channels (CH5, CH6 and CH7) of the general-purpose I/O unit 336 meet fast data communication compared with the respective input channels (CH1, CH2, CH3 and CH4) of the gas controller 322.

The mass flow controllers are memorized in the memory 314 of the substrate processing apparatus 100 as hardware position information. As shown in FIG. 6(a), for example, hardware position information of the MFC2 of the gas controller 322 is memorized as “MFC_VALUE_CH1” in the memory 314. Similarly, hardware position information of the MFC3 is memorized as “MFC_VALUE_CH2” in the memory 314, hardware position information of the MFC5 is memorized as “MFC_VALUE_CH3” therein, and hardware position information of the MFC6 is memorized as “MFC_VALUE_CH4” therein. On the other hand, hardware position information of the MFC1 of the general-purpose I/O unit 336 is memorized as “AUX_VALUE_CH5” in the memory 314, and hardware position information of the MFC4 is memorized as “AUX_VALUE_CH6” therein.

FIG. 6(a) shows a diagram illustrating a data definition table memorized in the memory 308 of the group control apparatus 302, which illustrates a data definition table 338 in which the hardware position information, identification information (identification codes: ID), and element name information (data names) are associated with one another (made into meta data). Setting and input of the data definition table 338 are performed by, for example, performing predetermined operation on the display section 310 by a user. The data names in the data definition table 338 can be optionally modified by a user.

A decimal point position and measurement unit of each data or the like may be defined as the hardware information, in addition to the hardware position information, identification information (data identifiers) and the like.

FIG. 6(b) shows a diagram illustrating a data collection table memorized in the memory 314 of the substrate processing apparatus 100, which illustrates a data collection table 340 in which collection data (for example, detection data to be inputted into respective input channels (CH1 to CH6): output values) and identification information of the collection data are associated with each other. In the data collection table 340, for example, respective collection data, identification codes (ID) as the identification information, and time stamps (detection time of the relevant data) are associated with one another.

FIG. 6(c) shows a diagram illustrating a data connection table memorized in the memory 308 of the group control apparatus 302, which illustrates a data connection table 342 in which the hardware information is associated with the collection data. More specifically, in the data connection table 342, identification codes (ID) of the collection data memorized with being associated with the identification codes (ID) and time stamps are correlated with identification codes (ID) of the hardware information such as the identification codes (ID) and data names. That is, the data definition table 338 is correlated with the data collection table 340 by the identification codes (ID). The data display table 342 is displayed on the display screen 344 of the display section 310. It is acceptable that when a data name in the data connection table 342 of FIG. 6(c) is accessed, hardware information such as hardware position information in the data definition table 338 of FIG. 6(a) is displayed. Furthermore, setting (input or the like) may be performed through the displayed screen.

Next, an example of a method of data collection in each of the substrate processing apparatus 100 and the group control apparatus 302 of the invention is described according to FIG. 7.

FIG. 7(a) shows a flowchart for illustrating data collection processing (S10) in the substrate processing apparatus 100. The data collection processing (S10) is executed by the second data collection program in the main controller 312 of the substrate processing apparatus 100.

In step S100, the main controller 312 memorizes collection data outputted from the sub controller 316 (detection data to be inputted into each input channel) into the memory 314. Next, the main controller 312 associates the collection data with identification information (identification codes: ID) of the collection data, and memorizes the associated data into the memory 314. As illustrated in FIG. 6(b), for example, when the mass flow controller 1 (MFC1) detects gas flow-rate detection data “10.000”, the main controller 312 associates the data with ID “1” and a time stamp “2005/12/15 10:11:59.190” with reference to the data definition table 338, and then memorizes (accumulates) the associated data into the memory 314.

In step S105, the main controller 312 determines whether collection data or the like are requested from the controller 306 of the group control apparatus 302. In the case that such a request is presented, processing is advanced to step S110, and in another case, processing is returned to the step S100.

In step S110, the main controller 312 transmits the collection data or the like collected (memorized) by the memory 314 to the controller 306 of the group control apparatus 302. Then, processing is returned to the step S100.

FIG. 7(b) shows a flowchart for illustrating data connection processing (S20) in the group control apparatus 302. The data connection processing (S20) is executed by the first data collection program in the controller 306 of the group control apparatus 302.

In step S200, the controller 306 associates hardware position information, element name information (data name) set by a user, and identification information (identification codes: ID) with one another (makes these kinds of information into meta data). Next, the controller 306 stores such associated data into the memory 308. As illustrated in FIG. 6(a), for example, the controller 306 associates the hardware position information “AUX_VALUE_CH5” with the ID “1” and the data name “MFC1_VALUE_N2-1”, and then memorizes such associated information into the memory 308.

In step S205, the controller 306 requests, to the main controller 312 of the substrate processing apparatus 100, data including collection data memorized in the memory 314 (detection data inputted into each input channel) associated with identification information (identification codes: ID) of the collection data. Next, the controller 306 memorizes data transmitted from the main controller 312 of the substrate processing apparatus 100 into the memory 308.

In step S210, the controller 306 correlates the data memorized in the memory 308 in the step S200 with data memorized in the memory 308 in the step S205. That is, the controller 306 correlates identification numbers (ID) of the data names memorized with being correlated with identification codes (ID), with identification numbers (ID) of the collection data and time stamps being memorized with being correlated with identification codes (ID). Next, the controller 306 memorizes such correlated data into the memory 308. As illustrated in FIG. 6(c), for example, the controller 306 correlates the data name “MFC1_VALUE_N2-1”, the time stamp “2005/12/15 10:11:59.190”, and the gas flow-rate detection data “10.000” detected by the mass flow controller 1 (MFC1) with one another using ID “1”, and then memorizes such correlated data into the memory 308.

In step S215, the controller 306 displays the correlated data (for example, the data display table 342), which were memorized in the memory 308 in the step S210, on the display screen 344 of the display section 310. Then, processing is returned to the step S205.

The data name is correlated with the collection data as above, thereby what is shown by each collection data can be easily determined, and the collection data can be easily analyzed and used. Moreover, if a user optionally modifies the hardware information (such as a data name and a decimal point position and measurement unit of each data), the hardware position information and the data name are associated with each other (made into meta data) by the data definition table 338, data mapping between each detection data and a data name at a side of the substrate processing apparatus 100 can be kept without modifying the data collection program. Moreover, the administrative apparatus can thus respond to a request of modifying hardware information (data name) from a user, in addition, it can easily respond to change in system configuration (layout change of hardware such as sensors).

Moreover, the hardware position information (for example, AUX_VALUE_CH1), which is not easily handled by a user, is associated with optional hardware information (such as data name), thereby a user can easily determine what is shown by the collection data (which sensor, actuator, or the like outputs the data).

Unlike the above embodiment, the substrate processing apparatus 100, rather than the group control apparatus 302, may associate the hardware information (data identifiers) such as hardware position information set by a user with the identification information (identification codes: ID) (make the hardware information and the identification information into meta data), and the substrate processing apparatus 100 may correlate identification numbers (ID) of the data names memorized with being associated with identification codes (ID), with identification numbers. (ID) of the collection data and time stamps memorized with being associated with identification codes (ID). That is, the data definition table 338 and the data connection table 342 may be memorized in the memory 314 of the substrate processing apparatus 100.

Moreover, unlike the above embodiment, the group control apparatus 302, rather than the substrate processing apparatus 100, may associate the collection data with the identification information of the collection data, and then memorizes (accumulates) such associated data. That is, the data collection table may be memorized in the memory 308 of the group control apparatus 302 (the second data collection program may be executed by the controller 306 of the group control apparatus 302).

A second embodiment for carrying out the invention is described.

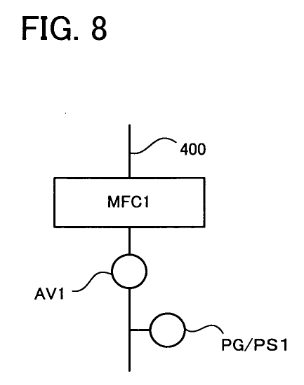

In the second embodiment for carrying out the invention, as in the first embodiment, a substrate processing apparatus is configured as a semiconductor manufacturing apparatus for embodying a processing apparatus in a manufacturing method of a semiconductor device (IC) as an example. FIG. 8 shows a schematic diagram showing a gas line as a part of a substrate processing apparatus to which the invention is applied, including a supply line for supplying gas such as deposition gas into a treatment furnace provided in the substrate processing apparatus.

As shown in FIG. 8, a gas line 400 has MFC (mass flow controller) 1, a valve AV1, and a gas pressure meter PG/PS1. In the second embodiment, many mass flow controllers, valves, and gas pressure meters are provided in addition to those as shown in FIG. 8. Moreover, the embodiment has the same configuration as in the first embodiment as shown in FIGS. 1 to 7 except for components being especially described.

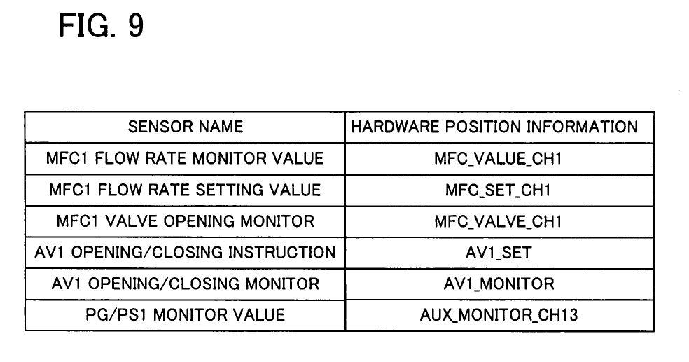

The MFC1, valve AV1, and gas pressure meter PG/PS1 are named as shown in FIG. 9 in order to manage apparatus data, in addition, attached with names of hardware position information to be memorized in the memory 314 (FIG. 6(a)) of the substrate processing apparatus 100, respectively.

Here, some trouble is assumed to occur in the gas line 400 shown in FIG. 8. In this case, to specify a cause of the trouble occurring in the gas line 400, all data caused by the MFC 1, valve AV1, and gas pressure meter PG/PS1 need to be investigated. From an apparatus layout shown in FIG. 8, that is, from an apparatus layout where the MFC 1, valve AV1, and gas pressure meter PG/PS1 are connected to the gas line 400 respectively, it is obviously known that the data caused by the MFC 1, valve AV1, and gas pressure meter PG/PS1 need to be investigated to investigate the trouble occurring in the gas line 400.

However, when data are monitored using the group control apparatus 302 (FIG. 5), a phenomenon that the MFC 1, valve AV1, and gas pressure meter PG/PS1 are mounted on the line 400 cannot be always viewed, and particular data relating to the gas line 400 are not always easily specified among various data processed by the group control apparatus 302.

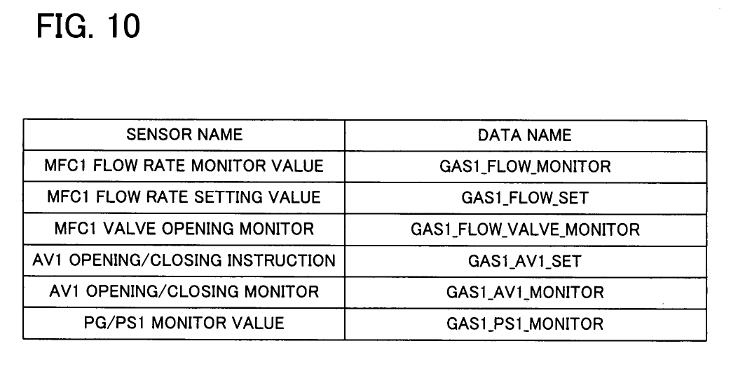

Therefore, data names are desirably determined such that data relating to the gas line 400 can be distinguished from other data using only the data names. For example, only the data relating to the gas line 400 are desirably attached with a prefix of “GAS_1”. FIG. 10 shows an example of data names determined such that only the data relating to the gas line 400 are attached with the prefix of “GAS_1”. The names are inputted into the data definition table 338, for example, through predetermined operation of the display section 310 by a user.

Data names are determined such that data relating to the gas line 400 can be distinguished from other data, so that when the data are shown in a graph for data analysis or the like, data attached with the prefix of “GAS_1” are extracted, thereby the relevant data (data relating to the gas line 400) can be easily extracted, consequently data analysis can be efficiently performed.

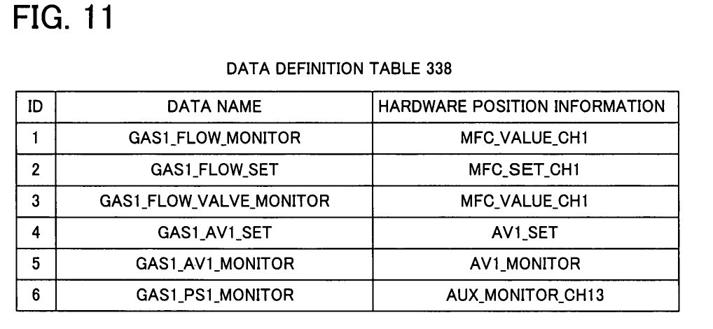

FIG. 11 shows a data definition table 338 using the data names determined in the above way. In the second embodiment, the data definition table 338 is connected with the data collection table 340 (FIG. 6) by identification codes (ID) similarly as in the first embodiment.

Various embodiments may be considered without being limited to the first and second embodiments.

For example, the group control apparatus is sometimes connected with various substrate processing apparatuses which have the same function (have the same film type, or perform the same processing), but are different in apparatus configuration from one another. In this case, when data detected from hardware (for example, a load lock chamber) having a plurality of substrate processing chambers are subjected to comparison, if the hardware as a comparison object exists in a different position in each apparatus configuration, a different point in apparatus configuration between them needs to be considered to specify data detected from the hardware as the object. Since much time has been taken for such specification so far, data analysis has not been able to be easily performed.

However, in the invention, since a user can optionally give a name to hardware, respective hardware can be unified by the name of “LL” or the like. In the example of the load lock chamber, a name such as “LL_Pressure1” or “LL1_N2_1” may be considered as such a name. Furthermore, a film type (CVD) is positioned at a head of a name to individually specify the substrate processing apparatus, which enables unification of names. In this case, when pressure in each load lock chamber of each substrate processing apparatus is analyzed, a film type name (CVD), a hardware name (LL), pressure (Pressure) and the like in a data name are confirmed, thereby data having the same hardware name (LL) and pressure (Pressure) and different number of a film type name (CVD) can be easily extracted.

The invention can be applied, as the substrate processing apparatus, not only to the semiconductor manufacturing apparatus, but also to an apparatus for processing a glass substrate such as an LCD apparatus. Moreover, the substrate processing apparatuses can be used not only for a sheet-feed apparatus or vertical apparatus, but also for a horizontal apparatus. Furthermore, the semiconductor manufacturing apparatus can be used even for CVD, oxidation, diffusion, and annealing, irrespective of a kind of furnace treatment.

### INDUSTRIAL APPLICABILITY

The invention can be used for a substrate processing system in which collection data transmitted from a substrate processing apparatus needs to be easily analyzed and used.

1. A substrate processing system including a substrate processing apparatus for performing processing to a substrate, and at least one group control apparatus connected to the substrate processing apparatus:
wherein the group control apparatus comprises,
accumulation part for accumulating collection data transmitted from the substrate processing apparatus;
storage part for correlating hardware position information of components configuring the substrate processing apparatus with previously set element name information, and then storing such correlated information; and
memory part for correlating information including the hardware position information correlated with the element name information, with the collection data transmitted from the substrate processing apparatus, and then memorizing such correlated information.

2. A substrate processing system including a substrate processing apparatus for performing processing to a substrate, and at least one group control apparatus connected to the substrate processing apparatus:
wherein the substrate processing apparatus comprises
a main controller that associates detection data from each sensor with time data when the detection data were obtained, and then memorizes such associated data, and
a sub controller that controls operation of each actuator based on setting data outputted from the main controller or detection data outputted from each sensor, and
the group control apparatus comprises
accumulation part for accumulating collection data transmitted from the main controller,
storage part for correlating hardware position information of components configuring the substrate processing apparatus with previously set element name information, and then storing such correlated information, and
memory part for correlating information including the hardware position information correlated with the element name information, with information including the detection data transmitted from the main controller associated with the time data when the detection data were obtained, and then memorizing the correlated information.

3. The group control apparatus in the substrate processing system according to claim 1.

4. A substrate processing apparatus including
a main controller that associates detection data from each sensor with time data when the detection data were obtained, and then memorizes such associated data, and
a sub controller that controls operation of each actuator based on setting data outputted from the main controller or detection data outputted from each sensor,
wherein the main controller comprises memory part for memorizing the detection data outputted from each sensor, and
the main controller connects information including hardware position information of components configuring the substrate processing apparatus correlated with previously set element name information, with information including the detection data from each sensor associated with the time data when the detection data were obtained, and then memorizes the correlated information.
